(19) United States
(12) Patent Application Publication
(10) Pub. No.: US 2015/0230013 A1
(43) Pub. Date: Aug. 13, 2015

(54) FIXING STRUCTURE AND ELECTRONIC DEVICE THEREWITH

(71) Applicant: Wistron Corporation, New Taipei City (TW)

(72) Inventors: Po-Jen Wu, New Taipei City (TW); Min-Hsiung Huang, New Taipei City (TW); Wei-Yi Lee, New Taipei City (TW)

(21) Appl. No.: 14/321,788

(22) Filed: Jul. 1, 2014

(30) Foreign Application Priority Data
Feb. 13, 2014 (TW) 103104774

(51) Int. Cl. H04R 1/02; H05K 7/12; H05K 7/20

(52) U.S. Cl. CPC H04R 1/025; H05K 7/20172; H05K 7/12

(57) ABSTRACT

An electronic device includes an electronic component and a fixing structure. The electronic component includes a fixing portion, and a fixing hole is formed on the fixing portion. The fixing structure is for fixing the electronic component on a base plate. The fixing structure includes a main body, a fastening portion, a fixing pillar and an engaging component. A supporting plane is formed on an end of the main body. The fastening portion is connected to the other end of the main body and for fastening the main body on the base plate. The fixing pillar is disposed on the supporting plane. The fixing pillar is inserted into the fixing hole for constraining the electronic component. The engaging component is connected to a side of the main body, and the engaging component presses the electronic component so as to engage the electronic component on the supporting plane.

### BACKGROUND OF THE INVENTION

1. Field of the Invention

The present invention relates to a fixing structure and an electronic device therewith for fixing an electronic component, and more specifically, to a fixing structure and an electronic device therewith for convenient assembly.

2. Description of the Prior Art

With the progress of technology, consumer electronic products have various functions. A common electronic product, such as a personal computer or a notebook computer, includes variety of internal electronic components so as to fit different requirements. However, the heat generated by the internal electronic components affects the stability and efficiency of the electronic product during operation. Hence, it is necessary to install a cooling device on a circuit board or on a casing of the electronic product, such as a conventional fan device, to reduce the temperature of the internal electronic components during operation, so that the electronic product can operate normally. The fan device is preferably to be assembled and disassembled easily and rapidly without tools, so that a user can conveniently maintain the fan device. However, the conventional fan device is often assembled with screws, and it results in inconvenience in disassembly and increase of cost. Therefore, it is an important issue to design a fixing structure of the fan device for easy assembly and disassembly with low cost.

### SUMMARY OF THE INVENTION

The present invention is to provide a fixing structure and an electronic device therewith for fixing an electronic component to solve the above drawbacks.

According to the disclosure, a fixing structure is for fixing an electronic component on a base plate. The electronic component has a fixing hole, and the fixing structure includes a main body, a fastening portion, a fixing pillar and an engaging component. The supporting plane is formed on an end of the main body. The fastening portion is connected to the other end of the main body and for fixing the main body on the base plate. The fixing pillar is disposed on the supporting plane of the main body and for inserting into the fixing hole of the electronic component, so as to constrain the electronic component from moving in a direction parallel to the supporting plane. The engaging component is connected to a side of the main body. The engaging component presses a part of the electronic component in a first direction perpendicular to the supporting plane as the fixing pillar is inserted into the fixing hole of the electronic component, so as to engage the electronic component on the supporting plane.

According to the disclosure, the electronic component further includes a fixing portion, the fixing portion includes the fixing hole, and the engaging component presses the fixing portion of the electronic component so as to engage the fixing portion on the supporting plane.

According to the disclosure, the fixing structure further includes a resilient supporting portion connected to another side of the main body different from the side connected to the engaging component, the resilient supporting portion supports the electronic component in a second direction opposite to the first direction with the supporting plane of the main body, and the engaging component presses the resilient supporting portion as the engaging component engages the electronic component on the supporting plane so that the resilient supporting portion resiliently deforms and provides resilient restoring force to the electronic component. The resilient supporting portion drives the electronic component to move in the first direction to separate the electronic component from the supporting plane as the engaging component is not engaged with the electronic component.

According to the disclosure, the main body, the fastening portion, the fixing pillar, the engaging component and the resilient supporting portion are integrally formed.

According to the disclosure, the fastening portion is a thread hole, the fixing structure further includes a fastening component, a through hole is formed on the base plate, and the fastening component is inserted into the through hole to fasten on the fastening portion so as to fix the main body on the base plate.

According to the disclosure, the engaging component includes an engaging portion, an resilient arm portion and an operation portion, the engaging portion is for engaging with the fixing portion, an end of the resilient arm portion is connected to the main body and the other end is connected to the engaging portion, the operation portion is connected to the engaging portion, and the operation portion drives the engaging portion to move as the operation portion is pressed so that the engaging portion separates from the fixing portion.

According to the disclosure, the fixing structure further includes a resilient component disposed on the main body and contacting with the main body and the fixing portion, and the resilient component absorbs vibration generated by the electronic component during operation.

According to the disclosure, the fixing structure further includes a resilient component disposed on the main body and contacting with the main body and the fixing portion, the resilient component provides resilient restoring force to the electronic component as the engaging component is engaged with the electronic component, and the resilient component absorbs vibration generated by the electronic component during operation.

According to the disclosure, an electronic device includes a base plate, an electronic component and a fixing structure. The electronic component includes a fixing portion, and a fixing hole is formed on the fixing portion. The fixing structure is for fixing the electronic component on the base plate. The fixing structure includes a main body, a fastening portion, a fixing pillar and an engaging component. The supporting plane is formed on an end of the main body. The fastening portion is connected to the other end of the main body and for fixing the main body on the base plate. The fixing pillar is disposed on the supporting plane of the main body and for inserting into the fixing hole of the electronic component, so as to constrain the electronic component from moving in a direction parallel to the supporting plane. The engaging component is connected to a side of the main body. The engaging component presses a part of the electronic component in a first direction perpendicular to the supporting plane as the fixing pillar is inserted into the fixing hole of the electronic component, so as to engage the electronic component on the supporting plane.

According to the disclosure, the electronic component is a cooling fan module or a speaker component.

Therefore, the electronic component, such as a cooling fan module, can be installed on the fixing structure directly. The main body and the fixing pillar can engage with the electronic component so as to constrain the electronic component from moving in the three axial directions perpendicular to one another, so that the electronic component can be firmly fixed on the fixing structure. Because the electronic component is directly installed on the fixing structure, it is unnecessary to fix the electronic component with any tools or screws, and the assembly of the electronic device becomes more convenient. In addition, the resilient supporting component and the resilient component can provide resilient recovering force to drive the electronic component to separate from the fixing structure more easily during disassembly. Furthermore, the main body, the fasting potion, the fixing pillar, the engaging component and the resilient supporting component portion can be integrally formed so as to reduce the cost of mold manufacture and assembly. In conclusion, the present invention provides the fixing structure and the electronic device therewith capable of easy assembly and disassembly with low cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an electronic device according to the embodiment of the present invention.

FIG. 2 is a partial exploded diagram of the electronic device according to the embodiment of the present invention.

FIG. 3 is a diagram of a fixing structure according to the embodiment of the present invention.

FIG. 4 is an exploded diagram of the fixing structure according to the embodiment of the present invention.

FIG. 5 and FIG. 6 are partial enlarged diagrams of the electronic device in different statuses according to the embodiment of the present invention.

FIG. 7 is a diagram of a fixing structure according to another embodiment of the present invention.

### DETAILED DESCRIPTION

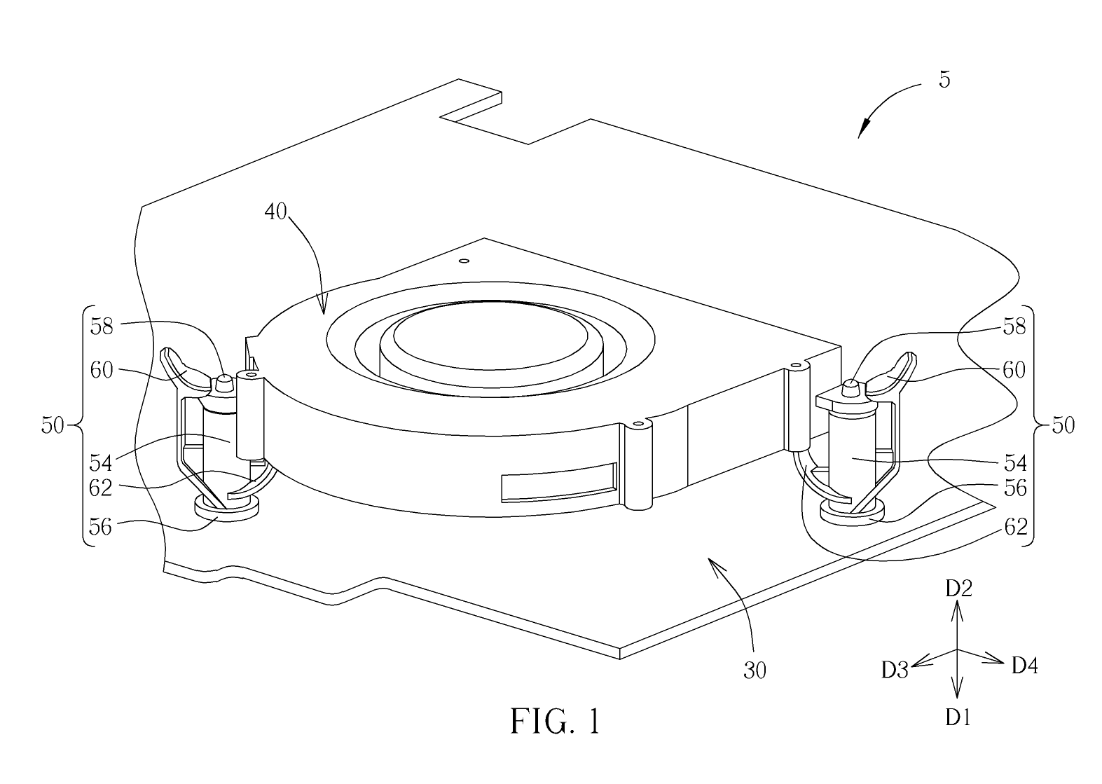

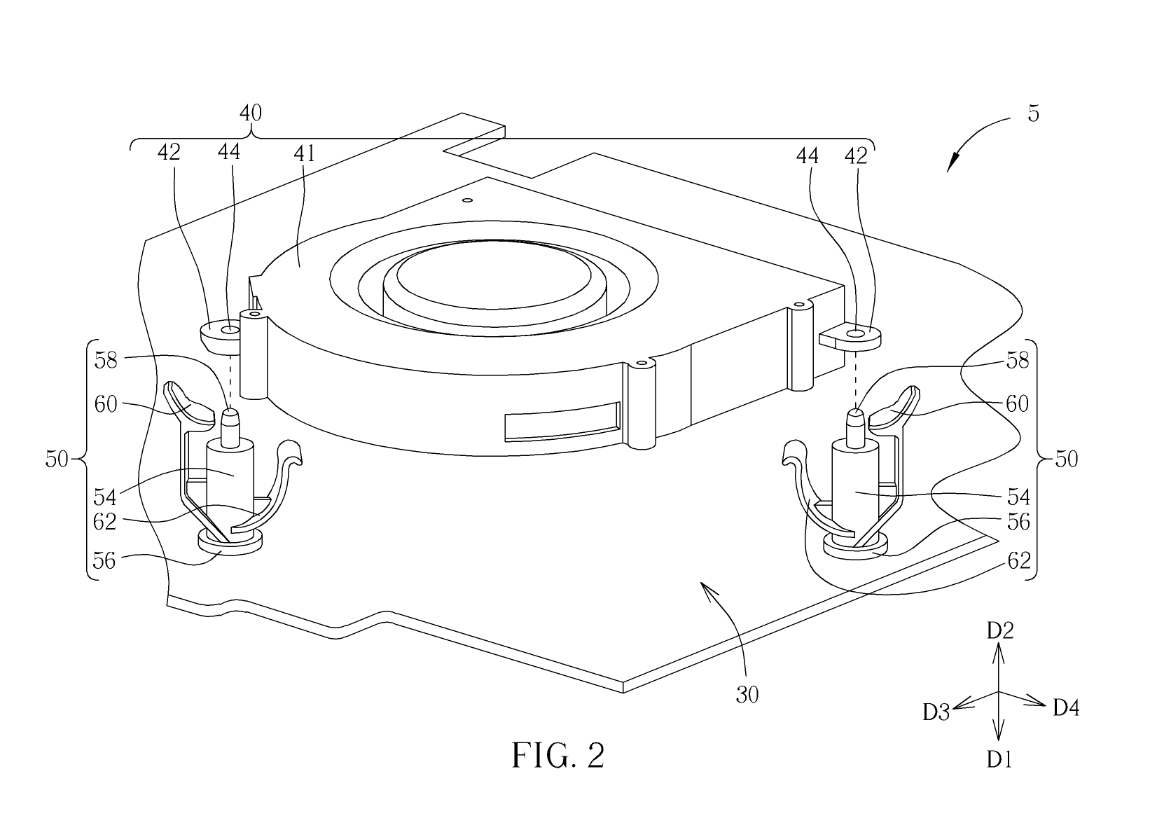

Please refer to FIG. 1 and FIG. 2. FIG. 1 is a schematic diagram of an electronic device 5 according to the embodiment of the present invention. FIG. 2 is a partial exploded diagram of the electronic device 5 according to the embodiment of the present invention. The electronic device 5 includes abase plate 30, an electronic component 40, and at least one fixing structure 50 for fixing the electronic component 40 on the base plate 30. In this embodiment, the electronic component 40 can be a cooling fan module. The electronic component 40 includes a body 41 and at least one fixing portion 42, the fixing portion 42 protrudes from the body 41, and a fixing hole 44 is formed on the fixing portion 42. In this embodiment, the electronic component 40 includes two fixing portions 42, and each fixing portion 42 can be a protruding ear. The electronic component 40 is not limited to a cooling fan module, and the electronic component 40 can be a speaker component, a storage device or an internal electronic component for computer operation. The fixing structure 50 is for fixing the electronic component 40, and the fixing structure 50 includes a main body 54, a fastening portion 56, a fixing pillar 58 and an engaging component 60. In this embodiment, the electronic component 40 includes two fixing portions 42, and the electronic device 5 includes two fixing structures 50 correspondingly. The numbers and positions of the above-mentioned components are not limited to this embodiment, and it depends on the practical requirement.

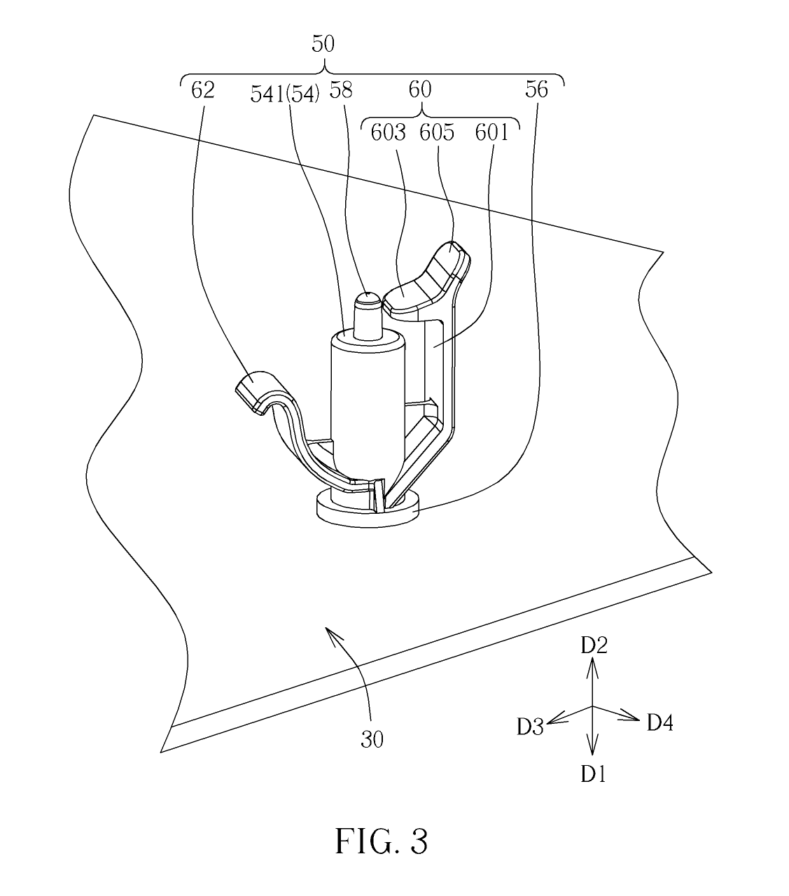

Please refer to FIG. 2 and FIG. 3. FIG. 3 is a diagram of the fixing structure 50 according to the embodiment of the present invention. A supporting plane 541 is formed on an end of the main body 54. A fastening portion 56 is connected to the other end of the main body 54 and is for fixing the main body 54 on the base plate 30. The engaging component 60 is connected to a side of the main body 54, and the engaging component 60 includes a resilient arm portion 601 and an engaging portion 603. An end of the resilient arm portion 601 is connected to the main body 54, and a free end of the resilient arm portion 601 is connected to the engaging portion 601. The engaging portion 603 presses the fixing portion 42 of the electronic component 40 in a first direction D1 perpendicular to the supporting plane 541 as the fixing pillar 58 is inserted into the fixing hole 44 of the electronic component 40, so as to engage the fixing portion 42 of the electronic component 40 on the supporting plane 541 to constrain the electronic component 40 from moving perpendicularly to the supporting plane 541. Simultaneously, the supporting surface 541 supports the fixing portion 42 in a second direction D2 opposite to the first direction D1.

The engaging portion 603 can be a plate structure, a hook structure or a collar structure. The fixing pillar 58 is disposed on the supporting plane 541 of the main body 54 and for inserting into the fixing hole 44 of the electronic component 42, so as to constrain the electronic component 40 from moving in a third direction D3 parallel to the supporting plane 541 and a fourth direction D4 perpendicular to the third direction D3, so that a parallel movement of the electronic component 40 can be constrained. The first direction D1, the third direction D3 and the fourth direction D4 are perpendicular to one another, so that the main body 54, the fixing pillar 58 and the engaging portion 603 constrain the electronic component 40 from moving in three directions of the first direction D1, the second direction D2 and the third direction D3, that is the perpendicular direction and the parallel direction. Hence, the electronic component 40 can be constrained in three axial directions, and the electronic component 40 can be firmly fixed on the fixing structure 50.

Furthermore, the fixing structure 50 includes a resilient supporting portion 62 connected to another side of the main body 54 different from the side connected to the engaging component 60. In this embodiment, the main body 54, the fastening portion 56, the fixing pillar 58, the engaging component 60 and the resilient supporting portion 62 can be integrally formed so as to reduce the cost of mold manufacture and assembly, and the above-mentioned components can be made of resilient plastic material. The resilient supporting portion 62 supports the electronic component 40 in the second direction D2 with the supporting plane 541 of the main body 54. The electronic component 40 presses the resilient supporting portion 62 as the engaging portion 603 engages the fixing portion 42 of the electronic component 40 on the supporting plane 541, so that the resilient supporting portion 62 resiliently deforms and provides resilient restoring force to the electronic component 40 in the second direction D2 so as to support the electronic component 40. In addition, the resilient supporting portion 62 drives the electronic component 40 to move in the second direction D2 to separate the electronic component 40 from the supporting plane 541 as the engaging portion 603 is not engaged with the electronic component 40, so that the electronic component 40 can be disassembled more easily.

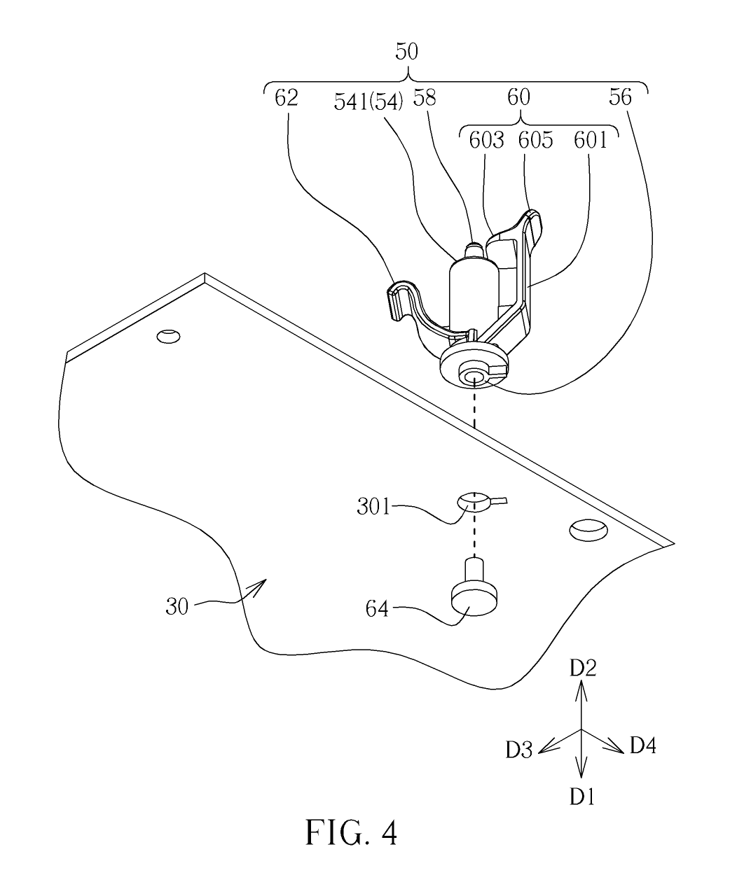

Please refer to FIG. 4. FIG. 4 is an exploded diagram of the fixing structure 50 according to the embodiment of the present invention. The fixing structure 50 further includes a fastening component 64, a through hole 301 is formed on the base plate 30, and the fastening component 64 is inserted into the through hole 301 to fasten on the fastening portion 56 so as to fix the main body 54 on the base plate 30. In this embodiment, the fastening portion 56 can be a thread hole, and the fastening component 64 can be correspondingly a screw for screwing in the thread hole. The present invention is not limited to this embodiment, the fastening portion 56 can be a tenon or a hook structure, and the fastening component 64 can be a C-shaped ring. The fastening component 64 can be omitted, and the fastening portion 56 can be directly fixed on the base plate 30. Besides, the base plate 30 can be a circuit board or a casing such as a computer casing, and it depends on the practical requirements.

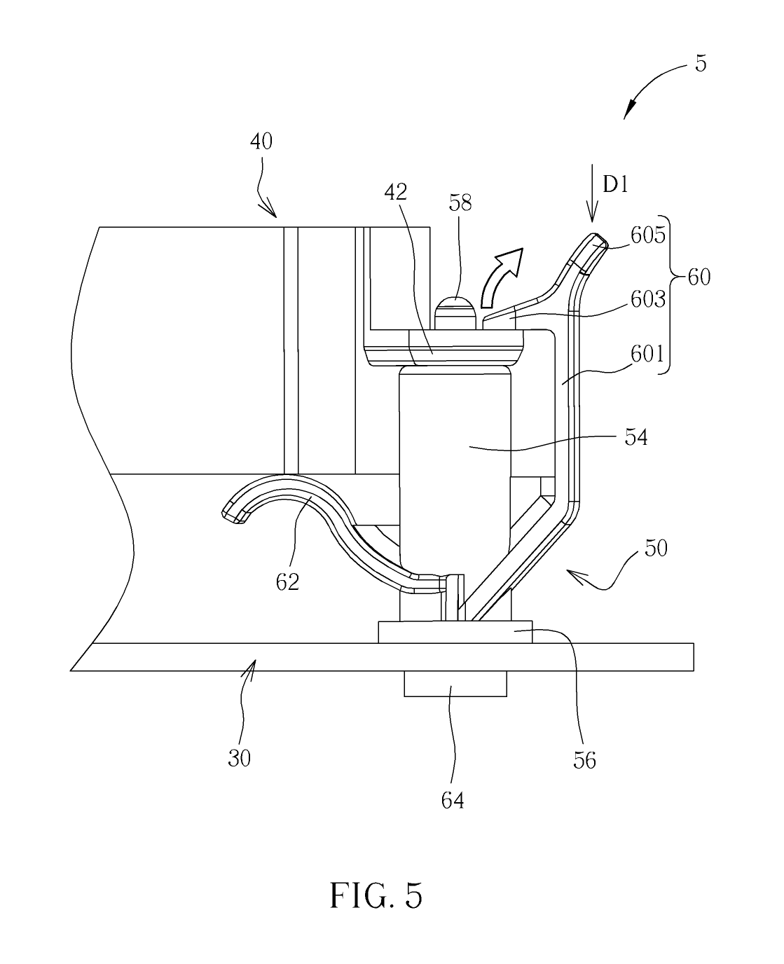

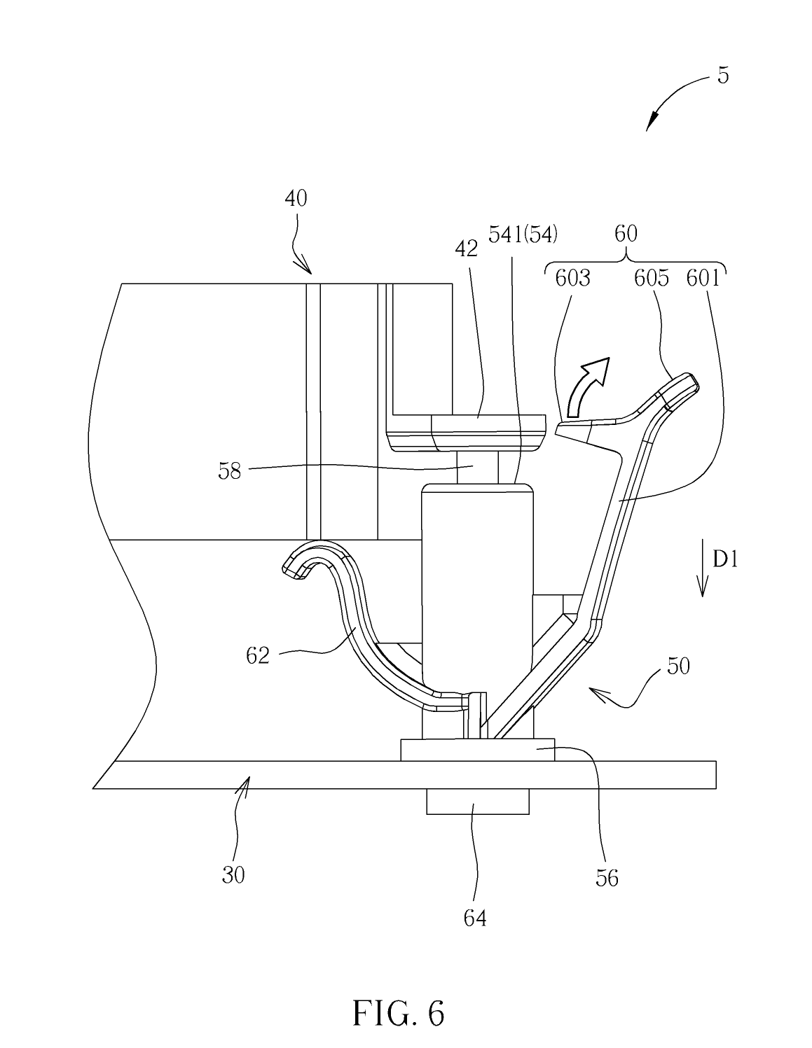

Please refer to FIG. 5 and FIG. 6. FIG. 5 and FIG. 6 are partial enlarged diagrams of the electronic device 5 in different statuses according to the embodiment of the present invention. The engaging component 60 further includes an operation portion 605 connected to the engaging portion 603. The operation portion 605 can be operated to drive the engaging portion 603 to move so that the engaging portion 603 can engage with or separate from the fixing portion 42 of the electronic component 40. For example, the operation portion 605 can be pressed downward in the first direction D1, and the operation portion 605 drives the engaging portion 603 to rotate in a direction of an arrow shown in FIG. 5 so as to separate the engaging portion 603 from the fixing portion 42. That is, the status of the engaging portion 603 shown in FIG. 5 is switched to another status in FIG. 6. Simultaneously, the resilient supporting portion 62 provides resilient restoring force to the electronic component 40 so as to drive the electronic component 40 to move in the second direction D2. That is, the electronic component 40 pops up to separate from the supporting plane 541 and the engaging portion 603, so that the electronic component 40 can be disassembled and taken away much easier.

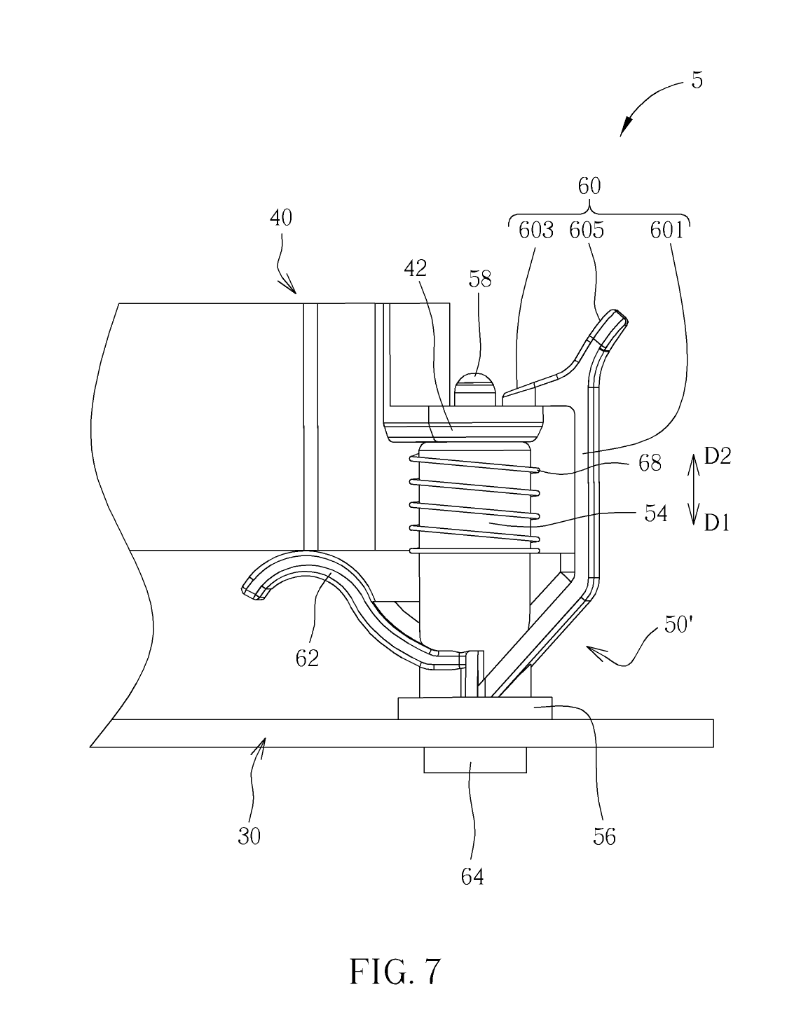

Please refer to FIG. 7. FIG. 7 is a diagram of a fixing structure 50′ according to another embodiment of the present invention. Components with same structure of the fixing structure 50′ as ones in the fixing structure 50 of the aforesaid embodiment are not reiterated here. The difference between the fixing structure 50′ in this embodiment and the fixing structure 50 of the aforesaid embodiment is that the fixing structure 50′ further includes a resilient component 68 sheathing on the main body 54. Two ends of the resilient component 68 respectively contact with a protruding structure of the man body 54, such as a root portion of the resilient arm portion 601 or somewhere appropriate, and the fixing portion 42. The resilient component 68 absorbs vibration generated by the electronic component 40 during operation, as the electronic component 40 is pressed by the engaging portion 603 in the first direction D1. The resilient component 68 further provides resilient restoring force to the electronic component 40 as the operation portion 605 drives the engaging portion 603 to rotate to separate the engaging portion 603 from the fixing portion 42, so that the electronic component 40 can be disassembled and taken away much easier. The resilient component 68 can be a spring or an elastic rubber. In another embodiment, the resilient component 68 can be disposed inside the main body 54. Besides, in another embodiment, the fixing structure 50 can include no resilient supporting portion 62 and only include the resilient component 68.

In contrast to the prior art, the electronic component, such as a cooling fan module, can be installed on the fixing structure directly. The main body and the fixing pillar can engage with the electronic component so as to constrain the electronic component from moving in the three axial directions perpendicular to one another, so that the electronic component can be firmly fixed on the fixing structure. Because the electronic component is directly installed on the fixing structure, it is unnecessary to fix the electronic component with any tools or screws, and the assembly of the electronic device becomes more convenient. In addition, the resilient supporting component and the resilient component can provide resilient recovering force to drive the electronic component to separate from the fixing structure more easily during disassembly. Furthermore, the main body, the fasting portion, the fixing pillar, the engaging component and the resilient supporting component portion can be integrally formed so as to reduce the cost of mold manufacture and assembly. In conclusion, the present invention provides the fixing structure and the electronic device therewith capable of easy assembly and disassembly with low cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fixing structure for fixing an electronic component on a base plate, the electronic component having a fixing hole, and the fixing structure comprising:
a main body, a supporting plane being formed on an end of the main body;
a fastening portion connected to the other end of the main body and for fixing the main body on the base plate;
a fixing pillar disposed on the supporting plane of the main body and for inserting into the fixing hole of the electronic component, so as to constrain the electronic component from moving in a direction parallel to the supporting plane; and
an engaging component connected to a side of the main body, the engaging component pressing apart of the electronic component in a first direction perpendicular to the supporting plane as the fixing pillar is inserted into the fixing hole of the electronic component, so as to engage the electronic component on the supporting plane.

2. The fixing structure of claim 1, wherein the electronic component further comprises a fixing portion, the fixing portion comprises the fixing hole, and the engaging component presses the fixing portion of the electronic component so as to engage the fixing portion on the supporting plane.

3. The fixing structure of claim 1, further comprising a resilient supporting portion connected to another side of the main body different from the side connected to the engaging component, the resilient supporting portion supporting the electronic component in a second direction opposite to the first direction with the supporting plane of the main body, the engaging component pressing the resilient supporting portion as the engaging component engages the electronic component on the supporting plane so that the resilient supporting portion resiliently deforms and provides resilient restoring force to the electronic component, and the resilient supporting portion driving the electronic component to move in the second direction to separate the electronic component from the supporting plane as the engaging component is not engaged with the electronic component.

4. The fixing structure of claim 3, wherein the main body, the fastening portion, the fixing pillar, the engaging component and the resilient supporting portion are integrally formed.

5. The fixing structure of claim 1, wherein the fastening portion is a thread hole, the fixing structure further comprises a fastening component, a through hole is formed on the base plate, and the fastening component is inserted into the through hole to fasten on the fastening portion so as to fix the main body on the base plate.

6. The fixing structure of claim 2, wherein the engaging component comprises an engaging portion, a resilient arm portion and an operation portion, the engaging portion is for engaging with the fixing portion, an end of the resilient arm portion is connected to the main body and the other end is connected to the engaging portion, the operation portion is connected to the engaging portion, and the operation portion drives the engaging portion to move as the operation portion is pressed so that the engaging portion separates from the fixing portion.

7. The fixing structure of claim 3, further comprising a resilient component disposed on the main body and contacting with the main body and the fixing portion, the resilient component absorbing vibration generated by the electronic component during operation.

8. The fixing structure of claim 2, further comprising a resilient component disposed on the main body and contacting with the main body and the fixing portion, the resilient component providing resilient restoring force to the electronic component as the engaging component is engaged with the electronic component, and the resilient component absorbing vibration generated by the electronic component during operation.

9. The fixing component of claim 1, wherein the base plate is a circuit board or a casing.

10. An electronic device comprising:
a base plate;
an electronic component comprising a fixing portion, and a fixing hole being formed on the fixing portion; and
a fixing structure for fixing the electronic component on the base plate, the fixing structure comprising:
a main body, a supporting plane being formed on an end of the main body;
a fastening portion connected to the other end of the main body and for fixing the main body on the base plate;
a fixing pillar disposed on the supporting plane of the main body and for inserting into the fixing hole of the electronic component, so as to constrain the electronic component from moving in a direction parallel to the supporting plane; and
an engaging component connected to a side of the main body, the engaging component pressing a part of the electronic component in a first direction perpendicular to the supporting plane as the fixing pillar is inserted into the fixing hole of the electronic component, so as to engage the electronic component on the supporting plane.

11. The electronic device of claim 10, wherein the fixing structure further comprises a resilient supporting portion connected to another side of the main body different from the side connected to the engaging component, the resilient supporting portion supports the electronic component in a second direction opposite to the first direction with the supporting plane of the main body, the engaging component presses the resilient supporting portion as the engaging component engage the electronic component on the supporting plane so that the resilient supporting portion resiliently deforms and provides resilient restoring force to the electronic component, and the resilient supporting portion drives the electronic component to move in the second direction to separate the electronic component from the supporting plane as the engaging component is not engaged with the electronic component.

12. The electronic device of claim 11, wherein the main body, the fastening portion, the fixing pillar, the engaging component and the resilient supporting portion are integrally formed.

13. The electronic device of claim 10, wherein the fastening portion is a thread hole, the fixing structure further comprises a fastening component, a through hole is formed on the base plate, and the fastening component is inserted into the through hole to fasten on the fastening portion so as to fix the main body on the base plate.

14. The electronic device of claim 10, wherein the engaging component comprises an engaging portion, a resilient arm portion and an operation portion, the engaging portion is for engaging with the fixing portion, an end of the resilient arm portion is connected to the main body and the other end is connected to the engaging portion, the operation portion is connected to the engaging portion, and the operation portion drives the engaging portion to move as the operation portion is pressed so that the engaging portion separates from the fixing portion.

15. The electronic device of claim 11, wherein the fixing structure further comprises a resilient component disposed on the main body and contacting with the main body and the fixing portion, and the resilient component absorbs vibration generated by the electronic component during operation.

16. The electronic device of claim 10, wherein the fixing structure further comprises a resilient component disposed on the main body and contacting with the main body and the fixing portion, the resilient component provides resilient restoring force to the electronic component as the engaging component is engaged with the electronic component, and the resilient component absorbs vibration generated by the electronic component during operation.

17. The electronic device of claim 10, wherein the base plate is a circuit board or a casing.

18. The electronic device of claim 10, wherein the electronic component is a cooling fan module or a speaker component.
